(19) United States
(12) Patent Application Publication
(10) Pub. No.: US 2016/0312335 A1
(43) Pub. Date: Oct. 27, 2016

(54) METHOD FOR MANUFACTURING Ca-CONTAINING COPPER ALLOY

(71) Applicant: MITSUBISHI MATERIALS CORPORATION, Tokyo (JP)

(72) Inventors: Satoshi KUMAGAI, Osaka (JP); Takashi SONOHATA, Iwaki-shi (JP); Michiaki OHTO, Osaka (JP)

(73) Assignee: MITSUBISHI MATERIALS CORPORATION, Tokyo (JP)

(21) Appl. No.: 15/104,490

(22) PCT Filed: Dec. 8, 2014
(86) PCT No.: PCT/JP2014/082400

§ 371 Date: Jun. 14, 2016

(30) Foreign Application Priority Data
Dec. 17, 2013 (JP) 2013-260259

(51) Int. Cl. C22B 15/00; C22C 9/00; B22D 7/00; B22D 11/00; H01J 37/34; B22D 21/00; B22D 11/108; B22D 11/116; C23C 14/34; C22B 9/10; B22D 1/00

(52) U.S. Cl. CPC C22B 15/006; C22B 9/103; C22C 9/00; B22D 7/005; B22D 11/004; B22D 1/00; B22D 21/005; B22D 11/108; B22D 11/116; C23C 14/3414; H01J 37/3429

(57) ABSTRACT

In a method for manufacturing a Ca-containing copper alloy, a Ca addition step of adding Ca to molten copper is provided, and, in the Ca addition step, a copper-coated Ca material (20) obtained by coating a surface of a metallic Ca (21) with copper (22) is used. In the copper-coated Ca material (20), an oxygen content in the copper (22) that coats the metallic Ca (21) is preferably set to less than 100 ppm by mass.

### CROSS-REFERENCE TO RELATED PATENT APPLICATIONS

This application is a U.S. National Phase Application under 35 U.S.C. §371 of International Patent Application No. PCT/JP2014/082400, filed Dec. 8, 2014, and claims the benefit of Japanese Patent Application No. 2013-260259, filed Dec. 17, 2013, all of which are incorporated herein by reference in their entireties. The International Application was published in Japanese on Jun. 25, 2015 as International Publication No. WO/2015/093333 under PCT Article 21(2).

### FIELD OF THE INVENTION

The present invention relates to a method for manufacturing a Ca-containing copper alloy including a Ca addition step of adding Ca to molten copper.

### BACKGROUND OF THE INVENTION

A Ca-containing copper alloy has a variety of characteristics that are improved by the addition of Ca and is used as a material for a variety of components.

For example, Patent Documents 1 to 3 propose sputtering targets made of a Ca-containing copper alloy. These sputtering targets are used to form a wiring film in a thin film transistor (hereinafter, referred to as ‘TFT’), in a flat panel display such as a liquid crystal display, or an organic EL display.

Such the flat panel display has a structure in which a TFT and a display circuit are formed on a substrate made of glass, amorphous Si, silica, or the like. Large-size screens having a high definition have been in demand recently to realize an increase in the size and definition of thin screen televisions as display panels for which this type of TFT is used (TFT panels).

In the related art, as a wiring film for a gate electrode, a source electrode, a drain electrode, and the like in a large-size high-definition TFT panel, it has been common to use a wiring film made of an aluminum (Al)-based material; however, in recent years, in order to decrease the resistance of a wiring film, attempts have been made to use a wiring film made of a copper (Cu)-based material having a higher conductivity than Al.

A wiring film made of a Ca-containing copper alloy does not only have a lower specific resistance than an Al-based material but also has excellent adhesiveness to glass, amorphous Si, silica, or the like used to manufacture a substrate, and thus the wiring film made of a Ca-containing copper alloy is applied as a copper-based material used for the above-described wiring film in the TFT panel.

The above-described sputtering target used to form a wiring film on a substrate is manufactured by means of, for example, the steps of casting and hot rolling.

### CITATION LIST

### Patent Documents

[Patent Document 1] Japanese Unexamined Patent Application, First Publication No. 2009-215613

[Patent Document 2] Japanese Unexamined Patent Application, First Publication {06920/005216-US0/01512089.1} 2 No. 2011-044674

[Patent Document 3] Japanese Unexamined Patent Application, First Publication No. 2013-014808

### SUMMARY OF INVENTION

### Problems to be Solved by the Invention

When casting of the above-described Ca-containing copper alloy is carried out, generally, a Cu—Ca based alloy is used to add a predetermined amount of Ca to molten copper. In the Cu—Ca based alloy, since the component value of the based alloy varies due to component segregation or a surface oxidation layer, there is a concern that the concentration of Ca in the Ca-containing copper alloy may vary. In addition, since the Cu—Ca based alloy includes Ca oxide, there is a concern that a suspended substance may be generated during the casting of the Ca-containing copper alloy and the suspended substance (Ca oxide) may be incorporated into an ingot.

In addition, the direct addition of metallic Ca to molten copper instead of the Cu—Ca based alloy can also be considered. However, metallic Ca has a high vapor pressure, and thus the metallic Ca turns into metallic fumes when coming into contact with molten copper, the addition yield of Ca is low, and it is difficult to accurately adjust the concentration of Ca in the Ca-containing copper alloy. In addition, since metallic Ca is easily oxidized, there is a concern that a suspended substance may be generated during the casting of the Ca-containing copper alloy and the suspended substance (Ca oxide) may be incorporated into an ingot.

The present invention has been made in consideration of the above-described circumstances, and an object of the present invention is to provide a method for manufacturing a Ca-containing copper alloy in which the addition yield of Ca is high, the concentration of Ca can be accurately adjusted, the incorporation of Ca oxide is inhibited, and an ingot having an excellent surface quality can be obtained.

### Means for Solving the Problems

In order to achieve the above-described object, the method for manufacturing a Ca-containing copper alloy of the present invention is a method for manufacturing a Ca-containing copper alloy containing Ca, the method including a Ca addition step of adding Ca to molten copper, in which, in the Ca addition step, a copper-coated Ca material obtained by coating a surface of a metallic Ca with copper is used.

In the method for manufacturing a Ca-containing copper alloy in the above-described constitution, since the copper-coated Ca material obtained by coating the surface of a metallic Ca with copper is used in the Ca addition step of adding Ca to molten copper, it is possible to inhibit Ca turning into metallic fumes while being added to molten copper and to significantly improve the addition yield of Ca. In addition, since the metallic Ca is coated with copper, the component value of Ca in the copper-coated Ca material is stable. Therefore, it is possible to accurately adjust the concentration of Ca in the Ca-containing copper alloy and to obtain an ingot in which the concentration of Ca only varies to a small extent. In addition, since the surface of the metallic Ca is coated with copper, the generation of Ca oxide can be inhibited, and it becomes possible to manufacture a high-quality ingot into which Ca oxide is incorporated only to a small extent.

In the method for manufacturing a Ca-containing copper alloy of the present invention, it is preferable that, in the copper-coated Ca material, an oxygen content in the copper that coats the metallic Ca be set to less than 100 ppm by mass.

According to the method for manufacturing a Ca-containing copper alloy in the above-described constitution, since the oxygen content in the copper that coats the metallic Ca is set to less than 100 ppm by mass, the oxidation of the metallic Ca can be inhibited, and it is possible to obtain a high-quality ingot into which Ca oxide is incorporated only to a small extent.

In addition, in the method for manufacturing a Ca-containing copper alloy of the present invention, it is preferable that, in the copper-coated Ca material, the surface of the metallic Ca be coated with copper by process of thermal spraying or deposition.

According to the method for manufacturing a Ca-containing copper alloy in the above-described constitution, it becomes possible to reliably coat the surface of the metallic Ca with copper. In addition, the coating amount of copper can be relatively accurately adjusted, and it becomes possible to inhibit the variation of the component value of Ca in the copper-coated Ca material. Therefore, it is possible to accurately adjust the concentration of Ca in the Ca-containing copper alloy.

Furthermore, in the method for manufacturing a Ca-containing copper alloy of the present invention, it is preferable that, in the copper-coated Ca material, a volume ratio V_{Cu}/V_{Ca} of a volume V_{Cu} of the applied copper to a volume V_{Ca} of the metallic Ca be set in a range of 0.01≦V_{Cu}/V_{Ca}≦6.

According to the method for manufacturing a Ca-containing copper alloy in the above-described constitution, since the volume ratio V_{Cu}/V_{Ca} of the volume V_{Cu} of the applied copper to the volume V_{Ca} of the metallic Ca is set to 0.01 or greater, it is possible to sufficiently coat the surface of the metallic Ca with copper and to inhibit the metallic Ca turning into metallic fumes while being added to the molten copper. On the other hand, since the volume ratio V_{Cu}/V_{Ca} is set to 6 or smaller, it is possible to ensure the melting rate of the copper-coated Ca material.

In addition, in the method for manufacturing a Ca-containing copper alloy of the present invention, it is preferable that, in the copper-coated Ca material, a weight ratio W_{Cu}/W_{Ca} of a weight W_{Cu} of the applied copper to a weight W_{Ca} of the metallic Ca be set in a range of 0.1≦W_{Cu}/W_{Ca}≦35.

According to the method for manufacturing a Ca-containing copper alloy in the above-described constitution, since the weight ratio W_{Cu}/W_{Ca} of the weight W_{Cu} of the applied copper to the weight W_{Ca} of the metallic Ca is set to 0.1 or greater, it is possible to sufficiently coat the surface of the metallic Ca with copper and to inhibit the metallic Ca turning into metallic fumes while being added to the molten copper. On the other hand, since the weight ratio W_{Cu}/W_{Ca} is set to 35 or smaller, it is possible to ensure the melting rate of the copper-coated Ca material.

Furthermore, in the method for manufacturing a Ca-containing copper alloy of the present invention, it is preferable that the Ca-containing copper alloy have a composition in which a content of Ca is 0.01% by atom or higher and 10% by atom or lower and a remainder is copper and inevitable impurities.

The Ca-containing copper alloy having a composition in which the content of Ca is 0.01% by atom or higher and 10% by atom or lower and the remainder is copper and inevitable impurities is suitable as a material for a sputtering target which forms a wiring film as described above. Therefore, according to the method for manufacturing a Ca-containing copper alloy of the present invention, it is possible to obtain a sputtering target in which the concentration of Ca varies only to a small extent and with which a wiring film having excellent characteristics can be stably formed. In addition, since a high-quality ingot which allows the incorporation of an oxide only to a small extent is used as a material, it is possible to efficiently manufacture the above-described sputtering target.

In addition, in the method for manufacturing a Ca-containing copper alloy of the present invention, the copper-coated Ca material may have a granular form or a bulk form.

According to the method for manufacturing a Ca-containing copper alloy in the above-described constitution, since the copper-coated Ca material having a granular form or a bulk form is used, it is possible to add a predetermined amount of Ca to the molten copper, and to accurately adjust the concentration of Ca in the Ca-containing copper alloy. In addition, it becomes possible to reliably coat the surface of the metallic Ca with copper.

Furthermore, in the method for manufacturing a Ca-containing copper alloy of the present invention, the copper-coated Ca material may have a linear form or a rod form.

According to the method for manufacturing a Ca-containing copper alloy in the above-described constitution, since the copper-coated Ca material having a linear form or a rod form is used, it is possible to add a predetermined amount of Ca to the molten copper and to accurately adjust the concentration of Ca in the Ca-containing copper alloy.

### Effects of the Invention

According to the present invention, it is possible to provide a method for manufacturing a Ca-containing copper alloy in which the addition yield of Ca is high, the concentration of Ca can be accurately adjusted, the incorporation of Ca oxide is inhibited, and an ingot having excellent surface quality can be obtained.

### BRIEF DESCRIPTION OF THE DRAWINGS

FIG. 1 is an explanatory view illustrating an example of a continuous casting apparatus used in a method for manufacturing a Ca-containing copper alloy which is an embodiment of the present invention.

FIG. 2 is a flowchart illustrating the method for manufacturing a Ca-containing copper alloy which is the embodiment of the present invention.

FIG. 3 is a schematic explanatory view of a copper-coated Ca material used in the method for manufacturing a Ca-containing copper alloy which is the embodiment of the present invention.

### DETAILED DESCRIPTION OF THE INVENTION

Hereinafter, a method for manufacturing a Ca-containing copper alloy according to an embodiment of the present invention will be described with reference to the accompanying drawings.

In the method for manufacturing a Ca-containing copper alloy of the present embodiment, an ingot 1 having a composition in which the content of Ca is set to 0.01% by atom or higher and 10% by atom or lower and the remainder is copper and inevitable impurities is continuously cast. The ingot 1 serves as a material for a sputtering target used to form a Ca-containing copper alloy film, used as a wiring film in a semiconductor device, a flat panel display such as a liquid crystal or organic EL panel, a touch panel, or the like, on a substrate.

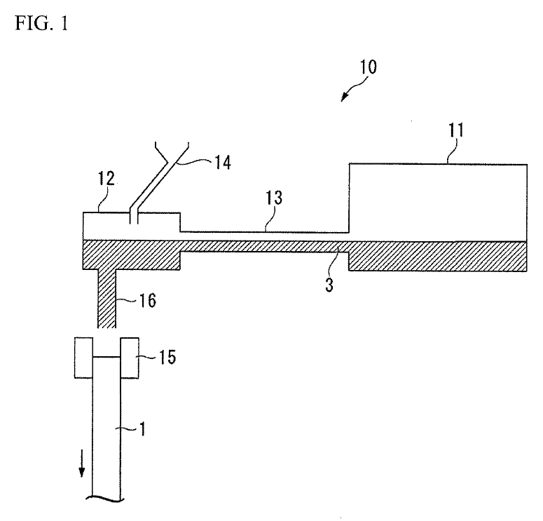

A continuous casting apparatus 10 used to carry out the method for manufacturing a Ca-containing copper alloy of the present embodiment will be described with reference to FIG. 1.

The continuous casting apparatus 10 includes a melting furnace 11 used to melt a copper raw material, a tundish 12 disposed on the downstream side of the melting furnace 11, a connecting gutter 13 that connects the melting furnace 11 and the tundish 12, addition device 14 provided in the tundish 12, a casting mold for continuous casting 15 that is disposed on the downstream side of the tundish 12, and a pouring nozzle 16 that supplies molten copper to the casting mold for continuous casting 15 from the tundish 12.

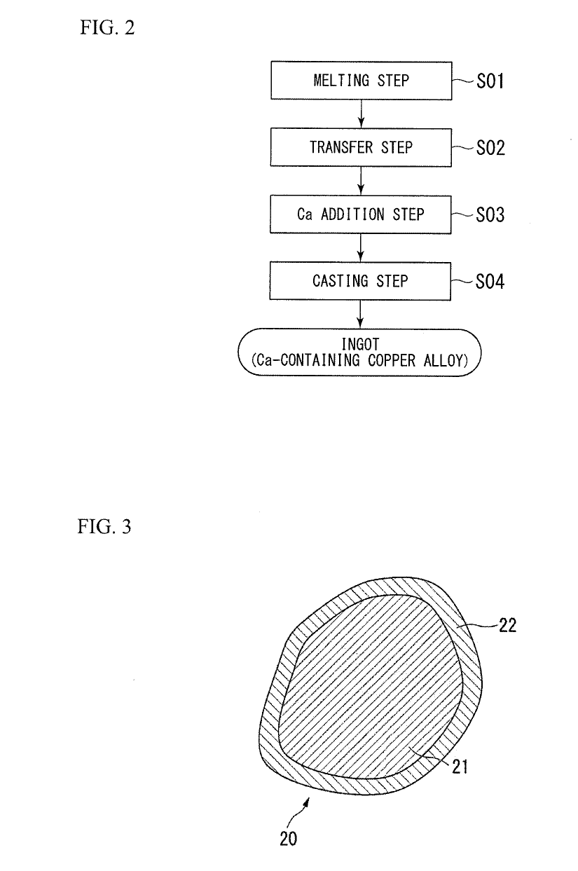

Next, the method for manufacturing a Ca-containing copper alloy of the present embodiment in which the continuous casting apparatus 10 illustrated in FIG. 1 is used will be described with reference to a flowchart of FIG. 2.

In the melting furnace 11, a copper raw material, for example, electrolytic copper having a purity of 99.9% by mass or higher is melted (melting step S01). In the melting furnace 11, the surface of molten copper 3 is sealed with carbon, and the atmosphere in the melting furnace 11 is set to an inert gas or a reducing gas.

The molten copper 3 is transferred to the tundish 12 through the connecting gutter 13 sealed with an inert gas or a reducing gas (transfer step S02).

In the tundish 12, Ca, which is an alloy element, is added to the stored molten copper 3 (Ca addition step S03).

The molten copper having adjusted components in the tundish 12 is continuously poured into the casting mold for continuous casting 15 from the pouring nozzle 16, and the molten copper 3 is cooled and solidified in the casting mold for continuous casting 15, thereby manufacturing the ingot 1 (casting step S04).

The ingot 1 produced from the casting mold for continuous casting 15 is continuously drawn using drawing device such as a pinch roll which is not illustrated.

In the Ca addition step S03, a copper-coated Ca material 20 illustrated in FIG. 3 is added to the molten copper 3.

The copper-coated Ca material 20 includes a core portion 21 made of metallic Ca and a coating portion 22 that coats the core portion 21 and has a granular form or a bulk form in the present embodiment. In order to obtain a granular copper-coated Ca material 20, metallic Ca having a grain diameter in a range of 1 mm to 20 mm may be used. In addition, in order to obtain a bulk-form copper-coated Ca material 20, metallic Ca having a grain diameter in a range of 20 mm to 100 mm may be used.

The coating portion 22 can be constituted of copper having an oxygen content set to less than 100 ppm by mass. In the present embodiment, oxygen-free copper having an oxygen content of 10 ppm by mass or lower is used. Furthermore, the coating portion 22 is formed on the surface of the core portion 21 made of metallic Ca by process of thermal spraying or deposition. The lower limit value of the oxygen content in the oxygen-free copper constituting the coating portion 22 is not particularly limited, and it is possible to use copper having a lower limit value of the oxygen content of 0.5 ppm by mass. (It is also possible to use copper containing no oxygen.)

In the copper-coated Ca material 20 of the present embodiment, the volume ratio V_{Cu}/V_{Ca} of the volume V_{Cu} of the coating portion 22 made of the oxygen-free copper to the volume V_{Ca} of the core portion 21 made of metallic Ca is set in a range of 0.01≦V_{Cu}/V_{Ca}≦6. The volume ratio V_{Cu}/V_{Ca} is more preferably 0.1≦V_{Cu}/V_{Ca}≦3 and still more preferably 1≦V_{Cu}/V_{Ca}≦2.

In addition, the weight ratio W_{Cu}/W_{Ca} of the weight W_{Cu} of the coating portion 22 made of the oxygen-free copper to the weight W_{Ca} of the core portion 21 made of the metallic Ca is set in a range of 0.1≦W_{Cu}/W_{Ca}≦35. The weight ratio W_{Cu}/W_{Ca} is more preferably 1≦W_{Cu}/W_{Ca}≦18 and still more preferably 10≦W_{Cu}/W_{Ca}≦12.

According to the method for manufacturing a Ca-containing copper alloy constituted as described above present embodiment, in the Ca addition step S03 in which Ca is added to the molten copper 3, the copper-coated Ca material 20 in which the coating portion 22 made of the oxygen-free copper is formed on the surface of the core portion 21 made of metallic Ca is used. Therefore, the core portion 21 made of metallic Ca does not come into contact with the molten copper 3 on the surface of the molten copper 3, and the core portion 21 made of metallic Ca comes into contact with the molten copper 3 after the coating portion 22 is melted in the molten copper 3, whereby it is possible to inhibit the added Ca turning into metallic fumes. Therefore, the addition yield of Ca can be significantly improved, it becomes possible to accurately adjust the concentration of Ca in the Ca-containing copper alloy, and it is possible to obtain the ingot 1 in which the concentration thereof varies only to a small extent. In addition, since the generation of metallic fumes is inhibited, it is possible to improve the operation environment.

Furthermore, in the copper-coated Ca material 20, since the core portion 21 is constituted of metallic Ca, the content of Ca varies only to a small extent in the copper-coated Ca material 20, and, in the Ca addition step S03, it becomes possible to accurately adjust the concentration of Ca in the Ca-containing copper alloy.

In addition, the generation of Ca oxide can be inhibited, and it becomes possible to manufacture a high-quality ingot 1 into which a suspended substance (an oxide such as Ca oxide) is incorporated only to a small extent.

In the copper-coated Ca material 20 of the present embodiment, since the coating portion 22 is constituted of oxygen-free copper having an oxygen content set to less than 100 ppm by mass, the generation of Ca oxide due to the oxidation of metallic Ca can be inhibited, and it becomes possible to obtain a high-quality ingot 1 into which Ca oxide is not incorporated.

In addition, in the copper-coated Ca material 20 of the present embodiment, since the coating portion 22 made of oxygen-free copper is formed on the surface of the core portion 21 made of metallic Ca by process of thermal spraying or deposition, it becomes possible to reliably coat the surface of the core portion 21 made of metallic Ca with oxygen-free copper. In addition, it is possible to relatively accurately control the coating amount of oxygen-free copper, and it becomes possible to inhibit the variation of the content of Ca in the copper-coated Ca material 20.

Furthermore, in the copper-coated Ca material 20 of the present embodiment, since the volume ratio V_{Cu}/V_{Ca} of the volume V_{Cu} of the coating portion 22 made of oxygen-free copper to the volume V_{Ca} of the core portion 21 made of metallic Ca is set to 0.01 or greater, and the weight ratio W_{Cu}/W_{Ca} of the weight W_{Cu} of the coating portion 22 made of oxygen-free copper to the weight W_{Ca} of the core portion 21 made of metallic Ca is set to 0.1 or greater, it is possible to sufficiently coat the core portion 21 made of metallic Ca with oxygen-free copper. Therefore, it is possible to inhibit the generation of metallic fumes or the generation of Ca oxide in the Ca addition step S03.

In addition, since the volume ratio V_{Cu}/V_{Ca} of the volume V_{Cu} of the coating portion 22 made of oxygen-free copper to the volume V_{Ca} of the core portion 21 made of metallic Ca is set to 6 or smaller, and the weight ratio W_{Cu}/W_{Ca} of the weight W_{Cu} of the coating portion 22 made of oxygen-free copper to the weight W_{Ca} of the core portion 21 made of metallic Ca is set to 35 or smaller, the coating portion 22 made of oxygen-free copper is not formed more than necessary, and it is possible to ensure the melting rate of the copper-coated Ca material 20. Therefore, even when the copper-coated Ca material is added to the molten copper 3 using the addition device 14 provided in the tundish 12, it is possible to reliably melt the copper-coated Ca material 20 in the tundish 12.

Furthermore, in the present embodiment, since the granular or bulk-form copper-coated Ca material 20 is used, in the Ca addition step S03, it is possible to add a predetermined amount of Ca to the molten copper 3 and to accurately adjust the concentration of Ca in the Ca-containing copper alloy. In addition, it is possible to reliably form the coating portion 22 made of oxygen-free copper on the surface of the core portion 21 made of metallic Ca and to inhibit the generation of metallic fumes in the Ca addition step S03.

In addition, in the method for manufacturing a Ca-containing copper alloy of the present embodiment, since the ingot 1 having a composition in which the content of Ca is 0.01% by atom or higher and 10% by atom or lower and the remainder is copper and inevitable impurities is continuously cast, it is possible to obtain a high-quality ingot 1 which does not allow the incorporation of an oxide and to efficiently manufacture a sputtering target. In addition, it is possible to obtain a sputtering target in which the concentration of Ca varies only to a small extent and with which an excellent wiring film can be stably formed.

Hitherto, the embodiment of the present invention has been described, but the present invention is not limited thereto and can be appropriately modified within the scope of the technical concept of the present invention.

For example, in the present embodiment, the copper-coated Ca material has been described to have a granular form or a bulk form, but the form thereof is not limited thereto, and the copper-coated Ca material may have a linear form or a rod form. In order to obtain a linear copper-coated Ca material, while there is no particular limitation, metallic Ca having a diameter φ in a range of 0.1 mm to 8 mm and a length of 10 mm or longer may be used. In order to obtain a rod-form copper-coated Ca material, while there is no particular limitation, metallic Ca having a diameter φ in a range of 8 mm to 40 mm and a length of 10 mm or longer may be used.

In addition, the continuous casting apparatus illustrated in FIG. 1 has been described to be used to manufacture the ingot, but the casting apparatus is not limited thereto, and a casting apparatus having a different constitution may be used.

Furthermore, the method for manufacturing an ingot used as a material for a sputtering target has been described, but the application of the ingot is not limited thereto, and the ingot may be a Ca-containing copper alloy used for a different application.

In addition, the method for manufacturing the ingot having a composition in which the content of Ca is 0.01% by atom or higher and 10% by atom or lower and the remainder is copper and inevitable impurities has been described, but the copper alloy is not limited thereto and may be a copper alloy containing Ca.

Furthermore, oxygen-free copper has been described as the copper that coats metallic Ca, but the copper is not limited thereto, and metallic Ca may be coated with a different kind of copper or copper alloy.

In addition, the copper-coated Ca material has been described to be added to the molten copper obtained by melting electrolytic copper, but the material of the molten copper is not limited thereto, and the copper-coated Ca material may be added to molten copper made of a different kind of copper or copper alloy.

Furthermore, in the present embodiment, the copper-coated Ca material has been described to be constituted so that the volume ratio V_{Cu}/V_{Ca} of the volume V_{Cu} of the coating portion made of oxygen-free copper to the volume V_{Ca} of the core portion made of metallic Ca falls in a range of 0.01≦V_{Cu}/V_{Ca}≦6, but the volume ratio V_{Cu}/V_{Ca} is not limited thereto and may be appropriately set and changed depending on the application status.

In addition, in the present embodiment, the copper-coated Ca material has been described to be constituted so that the weight ratio W_{Cu}/W_{Ca} of the weight W_{Cu} of the coating portion made of oxygen-free copper to the weight W_{Ca} of the core portion made of metallic Ca is set in a range of 0.1≦W_{Cu}/W_{Ca}≦35, but the weight ratio W_{Cu}/W_{Ca} is not limited thereto and may be appropriately set and changed depending on the application status.

### EXAMPLES

### Example 1

Hereinafter, the results of an evaluation test for evaluating the method for manufacturing a Ca-containing copper alloy of the present invention will be described.

(Copper-Coated Ca Material)

Oxygen-free copper wires which had an oxygen content set to less than 100 ppm by mass and a diameter φ of 3 mm (an oxygen content of 10 ppm by mass or less) were prepared, and a thermal spraying treatment was carried out on the surface of the metallic Ca by process of an arc spraying method or a flame spraying method, thereby producing copper-coated Ca materials. At this time, as the metallic Ca, a bulk-form metallic Ca having a grain diameter in a range of 5 mm to 10 mm and a φ10 mm×20 mm of rod-form copper were prepared.

The metallic Ca were evenly arranged on a metal net, and oxygen-free copper was evenly deposited on the metallic Ca while vibrating the metal net. The above-described operation was carried out once or more, and the surfaces of the metallic Ca being fully coated with copper were visually confirmed. The thickness of the applied copper was approximately 1 mm.

### Invention Examples 1 to 4

Electrolytic copper (5 kg) having a purity of 99.9% by mass or higher was melted at 1,150° C. in a vacuum melting furnace, then, the above-described copper-coated Ca materials were added to the molten copper held in an Ar atmosphere so that the concentrations of Ca reached the target concentrations shown in Table 1, and the solutions were poured into iron casting molds, thereby obtaining 70 mm×50 mm×150 mm ingots.

### Comparative Examples 1 and 2

Electrolytic copper (5 kg) having a purity of 99.9% by mass or higher was melted at 1,150° C. in a vacuum melting furnace, then, bulk-form Ca metal was added to the molten copper held in an Ar atmosphere so that the concentrations of Ca reached the target concentrations shown in Table 1, and the solutions were poured into iron casting molds, thereby obtaining 70 mm×50 mm×150 mm ingots.

(Generation status of suspended substance during addition of Ca) The surface of the molten copper was observed when the copper-coated Ca material or metallic Ca was added, and the generation status of a suspended substance (Ca oxide) on the surface of the molten copper was checked. In a case in which less than 10% of the molten metal surface was covered with a suspended substance, the generation status was evaluated as “A”, in a case in which 10% or more and less than 50% of the molten copper surface was covered with a suspended substance, the generation status was evaluated as “B”, and, in a case in which 50% or more of the molten copper surface was covered with a suspended substance, the generation status was evaluated as “C”.

(Incorporation Status of Oxide into Ingot)

The surface of the obtained ingot was observed, and the occurrence status of the incorporation of a suspended substance (an oxide such as Ca oxide) was checked. An ingot in which the incorporation of an oxide was not visually confirmed was evaluated as “A”, an ingot in which the incorporation of an oxide smaller than 5 mm was visually confirmed was evaluated as “B”, an ingot in which the incorporation of a number of 5 mm or larger oxide pieces was visually confirmed was evaluated as “C”, and an ingot in which the incorporation of a number of 10 mm or larger oxide pieces was visually confirmed was evaluated as “D”.

(Addition Yield of Ca)

The components of the obtained ingot were analyzed using an emission spectrophotometer, and the addition yield (% by mass) of Ca was computed (the amount of Ca in the ingot/the amount of added Ca×100) from the amount of added Ca and the analysis result of the amount of Ca in the ingot.

(Variation of Concentration of Ca in Ingot)

Analysis samples were taken from a top portion (20 mm position), a middle portion (80 mm position), and a bottom portion (140 mm position) of the ingot, and the concentrations (% by mass) of Ca were measured. An ingot in which the variation among the concentrations of Ca in the three samples was less than 10% was evaluated as “A”, an ingot in which the variation among the concentrations of Ca was 10% or more and less than 50% was evaluated as “B”, and an ingot in which the variation among the concentrations of Ca was 50% or more was evaluated as “C”.

The evaluation results are shown in Table 1.

TABLE 1

| | | | Target | | | | |
|---|---|---|---|---|---|---|---|
| | | | concentration | Suspended | | Addition | Variation of |
| | Added Ca | Applied copper | of Ca | substance during | Incorporation | yield of Ca | concentration |
| | material | material | (% by atom) | addition of Ca | into ingot | (%) | of Ca |
| Invention | Copper-coated | Oxygen-free copper | 0.1 | A | A | 97 | A |
| Example 1 | Ca material | O: 100 ppm or less | | | | | |
| | (bulk form) | | | | | | |
| Invention | Copper-coated | Oxygen-free copper | 10 | A | B | 95 | B |
| Example 2 | Ca material | O: 100 ppm or less | | | | | |
| | (bulk form) | | | | | | |
| Invention | Copper-coated | Oxygen-free copper | 0.1 | A | A | 98 | A |
| Example 3 | Ca material | O: 100 ppm or less | | | | | |
| | (rod form) | | | | | | |
| Invention | Copper-coated | Oxygen-free copper | 10 | A | B | 96 | B |
| Example 4 | Ca material | O: 100 ppm or less | | | | | |
| | (rod form) | | | | | | |
| Comparative | Metallic Ca | — | 1 | C | C | 48 | C |
| Example 1 | (bulk form) | | | | | | |
| Comparative | Metallic Ca | — | 1 | C | D | 40 | C |
| Example 2 | (bulk form) | | | | | | |

In Comparative Examples 1 and 2 to which metallic Ca was added, 50% or more of the surficial area of the molten copper was covered with a suspended substance such as an oxide during the addition of Ca. In addition, it was confirmed that a number of oxide pieces were incorporated into the surface of the ingot. It was assumed to be because a large amount of Ca oxide was generated.

Furthermore, in the ingots of Comparative Examples 1 and 2, the Ca addition yields were low, the variations of the concentration of Ca in the ingots were also great, and it was not possible to accurately adjust the concentration of Ca.

In contrast, in Invention Examples 1 to 4 to which the copper-coated Ca material was added, the generation of a suspended substance such as an oxide was inhibited during the addition of Ca, and the oxide was incorporated into the ingot only to a small extent. In addition, in the ingots of Invention Examples 1 to 4, the Ca addition yields were high, and the variations of the concentration of Ca in the ingot were also inhibited.

### Example 2

Next, copper-coated Ca materials shown in Table 2 were prepared as described below.

Copper wires having a diameter of 3 mm shown in Table 2 were prepared, and a thermal spraying treatment was carried out on the surface of the metallic Ca by process of an arc spraying method or a flame spraying method. At this time, the metallic Ca were evenly arranged on a metal net, and the copper materials were evenly deposited on the metallic Ca while vibrating the metal net. The above-described operation was carried out once or more, and the surfaces of the metallic Ca being fully coated with copper were visually confirmed.

For the obtained copper-coated Ca materials, the volume ratio V_{Cu}/V_{Ca} of the volume V_{Cu} of the applied copper to the volume V_{Ca} of the metallic Ca and the weight ratio W_{Cu}/W_{Ca} of the weight W_{Cu} of the applied copper to the weight W_{Ca} of the metallic Ca were computed. The results are shown in Table 2.

In addition, ingots were manufactured in the same order as for Invention Examples 1 to 4 in Example 1 using the copper-coated Ca materials prepared as described above, and “the generation status of a suspended substance during the addition of Ca”, “the incorporation status of an oxide into the ingot”, “the addition yield of Ca”, and “the variation of the concentration of Ca in the ingot” were evaluated in the same order as in Example 1. The evaluation results are shown in Table 3.

TABLE 2

| | | | Coated copper material | | |
|---|---|---|---|---|---|
| | Metallic Ca | | Oxygen content | Volume ratio | Weight ratio |
| | Shape | Size | (ppm by mass) | V_{Cu}/V_{Ca} | W_{Cu}/W_{Ca} |
| Invention Example 11 | Bulk form | Grain diameter of 20 mm | 9 | 0.03 | 0.15 |
| Invention Example 12 | Bulk form | Grain diameter of 50 mm | 85 | 3.01 | 15.13 |
| Invention Example 13 | Bulk form | Grain diameter of 95 mm | 32 | 0.54 | 2.7 |
| Invention Example 14 | Bulk form | Grain diameter of 95 mm | 98 | 5.96 | 29.98 |
| Invention Example 15 | Rod form | φ10 mm × 30 mm | 12 | 0.05 | 0.24 |
| Invention Example 16 | Rod form | φ10 mm × 50 mm | 51 | 0.12 | 0.63 |
| Invention Example 17 | Rod form | φ35 mm × 20 mm | 30 | 1.03 | 5.19 |
| Invention Example 18 | Rod form | φ35 mm × 100 mm | 72 | 4.83 | 24.32 |
| Invention Example 19 | Granular form | Grain diameter of 2 mm | 5 | 2.38 | 11.95 |
| Invention Example 20 | Linear form | φ3 mm × 50 mm | 19 | 2.01 | 10.13 |

TABLE 3

| | Target concentration of Ca | Suspended substance | Incorporation into | Addition yield of Ca | Variation of |
|---|---|---|---|---|---|
| | (% by atom) | during addition of Ca | ingot | (%) | concentration of Ca |
| Invention Example 11 | 0.2 | A | A | 99 | A |
| Invention Example 12 | 9.5 | B | B | 95 | B |
| Invention Example 13 | 2 | A | A | 98 | A |
| Invention Example 14 | 2 | A | A | 99 | A |
| Invention Example 15 | 3.5 | A | A | 98 | A |
| Invention Example 16 | 4.5 | A | A | 97 | A |
| Invention Example 17 | 7 | A | B | 98 | A |
| Invention Example 18 | 8.5 | A | B | 95 | A |
| Invention Example 19 | 0.5 | A | A | 99 | A |
| Invention Example 20 | 1.5 | A | A | 98 | A |

As shown in Tables 2 and 3, in Invention Examples 11 to 20, compared with Comparative Examples 1 and 2 described above, the generation of a suspended substance such as an oxide during the addition of Ca was inhibited, and the oxide was incorporated into the ingot only to a small extent. In addition, the Ca addition yields were high, and the variations of the concentration of Ca in the ingots were also inhibited. Even in the case of metallic Ca having a different form and size, it was confirmed that, when the metallic Ca was coated with a copper material in which the oxygen content was less than 100 ppm by mass, and the volume ratio V_{Cu}/V_{Ca} of the volume V_{Cu} of the applied copper to the volume V_{Ca} of the metallic Ca and the weight ratio W_{Cu}/W_{Ca} of the weight W_{Cu} of the applied copper to the weight W_{Ca} of the metallic Ca were set in predetermined ranges, it was possible to reliably add Ca.

The present invention provides an ingot in which the concentration of Ca can be accurately adjusted, the incorporation of Ca oxide can be inhibited, and the surface quality is excellent.

### REFERENCE SIGNS LIST

1 INGOT (Ca-CONTAINING COPPER ALLOY)
20 COPPER-COATED Ca MATERIAL
21 CORE PORTION
22 COATING PORTION

1. A method for manufacturing a Ca-containing copper alloy containing Ca, the method comprising:
a Ca addition step of adding Ca to molten copper,
wherein, in the Ca addition step, a copper-coated Ca material obtained by coating a surface of a metallic Ca with copper is used.

2. The method for manufacturing a Ca-containing copper alloy according to claim 1,
wherein, in the copper-coated Ca material, an oxygen content in the copper that coats the metallic Ca is set to less than 100 ppm by mass.

3. The method for manufacturing a Ca-containing copper alloy according to claim 1,
wherein, in the copper-coated Ca material, the surface of the metallic Ca is coated with copper by process of thermal spraying or deposition.

4. The method for manufacturing a Ca-containing copper alloy according to claim 1,
wherein, in the copper-coated Ca material, a volume ratio V_{Ca}/V_{Ca} of a volume V_{Cu} of the applied copper to a volume V_{Ca} of the metallic Ca is set in a range of 0.01≦V_{Cu}/V_{Ca}≦6.

5. The method for manufacturing a Ca-containing copper alloy according to claim 1,
wherein, in the copper-coated Ca material, a weight ratio W_{Cu}/W_{Ca} of a weight W_{Cu} of the applied copper to a weight W_{Ca} of the metallic Ca is set in a range of 0.1≦W_{Cu}/W_{Ca}≦35.

6. The method for manufacturing a Ca-containing copper alloy according to claim 1,
wherein the Ca-containing copper alloy has a composition in which a content of Ca is 0.01% by atom or higher and 10% by atom or lower and a remainder is copper and inevitable impurities.

7. The method for manufacturing a Ca-containing copper alloy according to claim 1,
wherein the copper-coated Ca material has a granular form or a bulk form.

8. The method for manufacturing a Ca-containing copper alloy according to claim 1,
wherein the copper-coated Ca material has a linear form or a rod form.
